(19) United States
(12) Patent Application Publication
(10) Pub. No.: US 2007/0170504 A1
(43) Pub. Date: Jul. 26, 2007

(54) THIN FILM TRANSISTOR SUBSTRATE AND METHOD OF FABRICATING THE SAME AND LIQUID CRYSTAL DISPLAY HAVING THE THIN FILM TRANSISTOR SUBSTRATE

(75) Inventor: Jong Woong Chang, Cheonan-Si (KR)

Correspondence Address: CANTOR COLBURN, LLP, 55 GRIFFIN ROAD SOUTH, BLOOMFIELD, CT, 06002, US

(73) Assignee: SAMSUNG ELECTRONICS CO., LTD, Suwon-Si (KR)

(21) Appl. No.: 11/534,877

(22) Filed: Sep. 25, 2006

(30) Foreign Application Priority Data
Jan. 9, 2006 (KR) 10-2006-0002344

(51) Int. Cl. H01L 27/12

(52) U.S. Cl. 257/347

(57) ABSTRACT

The present invention provides a thin film transistor substrate with a structure for reducing coupling capacitance between a data line and a pixel electrode, a method of fabricating the thin film transistor substrate, and a liquid crystal display having the thin film transistor substrate. The present invention provides a thin film transistor substrate, comprising a plurality of gate lines including a plurality of first gate lines formed in one direction on a substrate and a plurality of second gate lines formed in the same one direction while being spaced apart by a predetermined distance from the first gate lines; a plurality of data lines formed to intersect the plurality of first and second gate lines while being insulated therefrom; a plurality of unit pixels including a plurality of first unit pixels and a plurality of second unit pixels, each of the unit pixels are formed at intersection regions of the plurality of first and second gate lines and the plurality of data lines; and a plurality of shielding lines formed between the unit pixels such that a predetermined voltage is applied to the shielding lines. The present invention further provides a method of fabricating the thin film transistor substrate and a liquid crystal display having the thin film transistor substrate.

This application claims priority to Korean Patent Application No. 10-2006-0002344, filed on Jan. 9, 2006, and all the benefits accruing therefrom under 35 U.S.C. §119, and the contents of which in its entirety are herein incorporated by reference.

### BACKGROUND OF THE INVENTION

1. Field of the Invention

The present invention relates to a thin film transistor substrate, a method of fabricating the same and a liquid crystal display having the thin film transistor substrate. More particularly, the present invention relates to a thin film transistor substrate having a structure for reducing coupling capacitance between a data line and a pixel electrode, a method of fabricating the thin film transistor substrate, and a liquid crystal display having the thin film transistor substrate.

2. Description of the Related Art

Due to a desired tendency to widen a liquid crystal display (“LCD ”), an LCD has been developed with a wide screen implemented by reducing the number of signal lines in half. In such an LCD, two unit pixels are connected to one data line, and each of the two unit pixels is driven by a pair of gate lines to receive a data voltage using the same data line.

With the aforementioned configuration, each of the two unit pixels positioned between the data lines has a pixel electrode. Here, coupling capacitance between the data line and each of the pixel electrodes appears larger than that between the pixel electrodes. Accordingly, there is a problem in that a vertical stripe pattern is displayed due to a difference in coupling capacitance when the LCD is driven. To reduce the difference in coupling capacitance, a separation distance between the data line and the pixel electrode may be increased. However, increasing the separation distance between the data line and the pixel electrode inevitably deteriorates an aperture ratio of the two unit pixels.

### BRIEF SUMMARY OF THE INVENTION

The present invention is conceived to solve the aforementioned problems. Accordingly, an exemplary embodiment of the present invention provides a thin film transistor substrate including a shielding line for reducing coupling capacitance between a data line and a pixel electrode of a unit pixel without deteriorating an aperture ratio of a liquid crystal display, a method of fabricating the thin film transistor substrate, and a liquid crystal display having the thin film transistor substrate.

According to an exemplary embodiment of the present invention, a thin film transistor substrate includes a plurality of gate lines including a plurality of first gate lines formed in one direction on a substrate and a plurality of second gate lines formed in the same one direction while being spaced apart by a predetermined distance from the first gate lines; a plurality of data lines formed to intersect the plurality of gate lines while being insulated therefrom; a plurality of unit pixels including a plurality of first unit pixels and a plurality of second unit pixels, each of the unit pixels are formed at intersection regions of the plurality of gate lines and the plurality of data lines; and a plurality of shielding lines formed between the unit pixels such that a predetermined voltage is applied to the shielding lines.

The plurality of shielding lines may be formed on the data lines.

The plurality of shielding lines may be formed in parallel with the data lines.

The width of each of the plurality of shielding lines may be formed to be smaller than that of the data line.

A first thin film transistor of the first unit pixel may be connected to the first gate line, and a second thin film transistor of the second unit pixel is connected to the second gate line.

An organic film may be formed between the plurality of shielding lines and the data lines.

The plurality of shielding lines may be formed on at least one of the first gate lines and the second gate lines.

The plurality of shielding lines may be formed in parallel with the gate lines.

The width of each of the plurality of shielding lines may be formed to be smaller than that of the gate line.

The unit pixel further may include a storage capacitor electrode for maintaining a voltage applied to a liquid crystal.

The amplitude of the predetermined voltage applied to the plurality of shielding lines may be the same as a voltage applied to the storage capacitor electrode.

According to another exemplary embodiment of the present invention, a liquid crystal display (LCD) includes a thin film transistor substrate including a plurality of gate lines including a plurality of first gate lines formed in one direction on a substrate and a plurality of second gate lines formed in the same one direction on the substrate while being spaced apart by a predetermined distance from the first gate lines; a plurality of data lines formed to intersect the plurality of gate lines while being insulated therefrom; a plurality of unit pixels including a plurality of first unit pixels and a plurality of second unit pixels, each of the unit pixels are formed at intersection regions of the plurality of gate lines and the plurality of data lines; and a plurality of shielding lines formed between the unit pixels such that a predetermined voltage is applied to the shielding lines.

According to a further exemplary embodiment of the present invention, a method of fabricating a thin film transistor substrate includes forming a plurality of gate lines composed of a plurality of first gate lines formed in one direction on a substrate and a plurality of second gate lines formed in the same one direction on the substrate while being spaced apart by a predetermined distance from the first gate lines; forming a plurality of data lines formed to intersect the plurality of gate lines while being insulated therefrom; forming a plurality of unit pixels including a plurality of first unit pixels and a plurality of second unit pixels, each of the unit pixels are formed at intersection regions of the plurality of gate lines and the plurality of data lines; forming an organic film on the plurality of data lines; and forming a plurality of shielding lines formed between the unit pixels such that a predetermined voltage is applied to the shielding lines.

According to a still another exemplary embodiment of the present invention, an LCD includes a plurality of pixel rows including a plurality of pixels having switching elements; a plurality of pairs of first and second gate lines separated from each other and connected to the switching elements to transmit a gate-on voltage for turning on the switching elements; data lines connected to the switching elements to transmit a pixel voltage and each of which is connected to two adjacent pixel columns; an organic film formed on at least one of the data lines, first gate lines and second gate lines; and shielding lines formed on the organic film.

### BRIEF DESCRIPTION OF THE DRAWINGS

The above and other objects, features and advantages of the present invention will become apparent from the following description of exemplary embodiments given in conjunction with the accompanying drawings, in which:

FIG. 1A is a schematic plan view of an exemplary embodiment of a liquid crystal display (LCD) according to the present invention;

FIGS. 1B and 1C are schematic cross-sectional views taken along lines C-C and D-D, respectively shown in FIG. 1A;

FIG. 2 is a schematic plan view of another exemplary embodiment of an LCD according to the present invention;

FIGS. 3A to 3E are cross-sectional views illustrating a process of fabricating a thin film transistor substrate of the LCD shown in FIG. 2;

FIGS. 4A and 4B are graphs illustrating results of light leakage simulations of LCDs according to a prior art LCD and an LCD according to the present invention, respectively; and

FIG. 5 is a graph illustrating a comparison of coupling capacitance values between a data line and a pixel electrode according to the prior art and the present invention, respectively.

### DETAILED DESCRIPTION OF THE INVENTION

The invention will now be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments of the present invention are described herein with reference to cross section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present invention.

Hereinafter, the present invention will be described in detail with reference to the accompanying drawings.

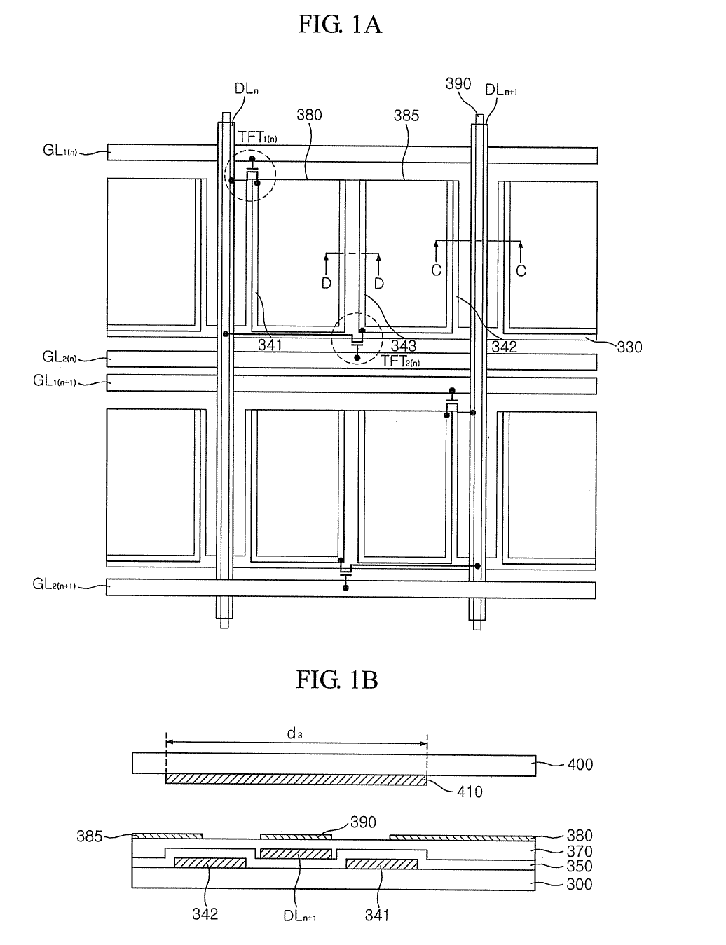

FIG. 1A is a schematic plan view of an exemplary embodiment of a liquid crystal display (“LCD ”) according to the present invention, and FIGS. 1B and 1C are schematic cross-sectional views taken along lines C-C and D-D, respectively, shown in FIG. 1A;

Referring to FIGS. 1A to 1C, the exemplary embodiment of the LCD according to the present invention comprises a thin film transistor substrate as a lower substrate, a common electrode substrate as an upper substrate positioned to face the thin film transistor substrate and a liquid crystal layer (not shown) formed between the two substrates. The liquid crystals of the liquid crystal layer are oriented in a desired direction with respect to the two substrates.

Referring to FIG. 1A, the thin film transistor substrate includes a plurality of gate lines that are formed on a transparent insulative substrate 300 (FIG. 1B) to transmit gate signals and are composed of a plurality of first gate lines GL₁₍ₙ₎ and GL₁₍ₙ₊₁₎ formed laterally on the substrate 300 and a plurality of second gate lines GL₂₍ₙ₎ and GL₂₍ₙ₊₁₎ formed while being spaced apart by a predetermined distance from the first gate lines GL₁₍ₙ₎ and GL₁₍ₙ₊₁₎; storage capacitor electrode lines 330 that are formed in parallel with the plurality of first and second gate lines and have storage capacitor electrodes; a plurality of data lines DLₙ and DLₙ₊₁ that are formed to intersect the plurality first and second gate lines while being insulated therefrom; a plurality of unit pixels that are composed of a plurality of first unit pixels and a plurality of second unit pixels formed at regions where the plurality of first and second gate lines and the plurality of data lines intersect each other; and a plurality of shielding lines 390 which are formed on the data lines and to which a predetermined voltage is applied.

The unit pixel composed of the first and second unit pixels comprises first and second thin film transistors TFT₁₍ₙ₎ and TFT₂₍ₙ₎, respectively, a first pixel electrode 380, a second pixel electrode 385, and storage capacitor electrodes 341, 342 and 343 extending from the storage capacitor electrode line 330. Each of the first and second thin film transistors TFT₁₍ₙ₎ and TFT₂₍ₙ₎ comprises a gate electrode connected to one of the first and second gate lines, a source electrode connected to the data line, a drain electrode connected to the pixel electrode, a gate insulation film and an active layer that are sequentially formed between the gate electrode and the source and drain electrodes, and an ohmic contact layer formed on at least a portion of the active layer. At this time, the ohmic contact layer may be formed on a portion of the active layer except a channel portion. The first thin film transistor TFT₁₍ₙ₎ allows a pixel signal supplied to the data line DLₙ to be charged to the first pixel electrode 380 in response to a signal supplied to the first gate line GL₁₍ₙ₎. Further, the second thin film transistor TFT₂₍ₙ₎ allows a pixel signal supplied to the data line DLₙ to be charged to the second pixel electrode 385 in response to a signal supplied to the second gate line GL₂₍ₙ₎.

Meanwhile, although all of the first and second unit pixels positioned between an n-th data line DLₙ and an (n+1)-th data line DLₙ₊₁ are connected to the n-th data line DLₙ in this exemplary embodiment, they are not limited thereto. Alternatively, a second unit pixel positioned between an (n−1)-th data line DLₙ₋₁ and the n-th data line DLₙ and the first unit pixel positioned between the n-th data line DLₙ and the (n+1)-th data line DLₙ₊₁ may be connected to the n-th data line DLₙ. Further, the exemplary embodiment of the LCD according to the present invention preferably performs a column inversion, but is not limited thereto.

The storage capacitor electrode lines 330 are formed in parallel with the second gate lines GL₂₍ₙ₎ and GL₂₍ₙ₊₁₎ while respectively being spaced apart by a predetermined distance from the second gate lines GL₂₍ₙ₎ and GL₂₍ₙ₊₁₎, and the storage capacitor electrodes 341, 342 and 343 extend from the storage capacitor electrode line 330 to be parallel with the data lines and are formed to partially be overlapped by the pixel electrodes 380 and 385. At this time, the storage capacitor electrodes comprise a first storage capacitor electrode 341 formed to partially be overlapped by the pixel electrode 380, a second storage capacitor electrode 342 formed to be partially overlapped by the pixel electrode 385, and a third storage capacitor electrode 343 formed to be partially overlapped by the pixel electrodes 380 and 385 in common.

Further, the storage capacitor electrode line 330 may be connected to a common voltage (Vcom) to be applied to the color filter substrate. Otherwise, a voltage identical with the common voltage may be separately applied to the storage capacitor electrode line 330. Although an additional storage capacitor electrode line is formed in this exemplary embodiment, it is not limited thereto, and alternatively, the storage capacitor electrodes 341, 342 and 343 may be formed to extend from the first or second gate line GL₁₍ₙ₎ or GL₂₍ₙ₎.

The plurality of shielding lines 390 are formed on the data lines to be parallel therewith, and the width of each of the plurality of shielding lines 390 is formed to be smaller than that of the data line. Preferably, the width of the data line is set to 5.5 μm, and the width of the shielding line 390 is set to 5 μm. Further, the plurality of shielding lines 390 is made of the same material as the pixel electrodes 380 and 385. The pixel electrodes 380 and 385 are generally made of a transparent conductive material such as indium tin oxide (ITO) or indium zinc oxide (IZO). Further, to minimize coupling capacitance between the data line and the pixel electrode due to a pixel signal applied to the data line, a voltage with the same amplitude as that of a voltage applied to the storage capacitor electrode is applied to the plurality of shielding lines 390 via the storage capacitor electrode line 330. That is, a voltage with the same amplitude as that of the common voltage applied to the color filter substrate is applied to the plurality of shielding lines 390.

Referring to FIG. 1B, a schematic cross-sectional view of the LCD of FIG. 1 taken along line C-C is illustrated. The thin film transistor substrate of the LCD comprises a transparent insulative substrate 300, storage capacitor electrodes 341 and 342 formed on the transparent insulative substrate, a gate insulation film 350 formed on the storage capacitor electrodes 341 and 342, a data line DLₙ₊₁ formed on the gate insulation film 350 and positioned between the first and second storage capacitor electrodes 341 and 342, an organic film 370 formed on the data line, a first pixel electrode 380 formed on the organic film 370 and positioned to partially overlap the first storage capacitor electrode 341, a second pixel electrode 385 formed on the organic film 370 and positioned to partially overlap the second storage capacitor electrode 342, and a shielding line 390 formed on the data line DLₙ₊₁. Preferably, the organic film 370 is formed to have a thickness of about 4 μm to about 6 μm.

Further, the color filter substrate positioned to face the thin film transistor substrate includes a black matrix 410 on the bottom of an insulation substrate 400 made of a transparent insulating material to prevent light leakage and optical interference between adjacent pixel regions; red, green and blue color filters (not shown); an overcoat film (not shown) formed on the color filters; and a common electrode (not shown) made of a transparent conductive material such as ITO or IZO on the overcoat film. With the formation of the plurality of shielding lines 390, a light leakage region can be decreased by at least 3 μm, thereby reducing the width d₃ of the black matrix 410 by at least 3 μm as compared with a conventional one.

Referring to FIG. 1C, a schematic cross-sectional view of the LCD of FIG. 1 taken along line D-D is illustrated. The thin film transistor substrate of the LCD comprises a transparent insulative substrate 300, a third storage capacitor electrode 343 formed on the transparent insulative substrate 300, a gate insulation film 350 and an organic film 370 that are sequentially formed on the entire surface of the substrate 300, and first and second pixel electrodes 380 and 385 that are formed on the organic film and positioned to partially overlap the third storage capacitor electrode 343.

Further, the color filter substrate positioned to face the thin film transistor substrate has a black matrix 410 on the bottom of an insulation substrate 400 made of a transparent insulating material to prevent light leakage and optical interference between adjacent pixel regions.

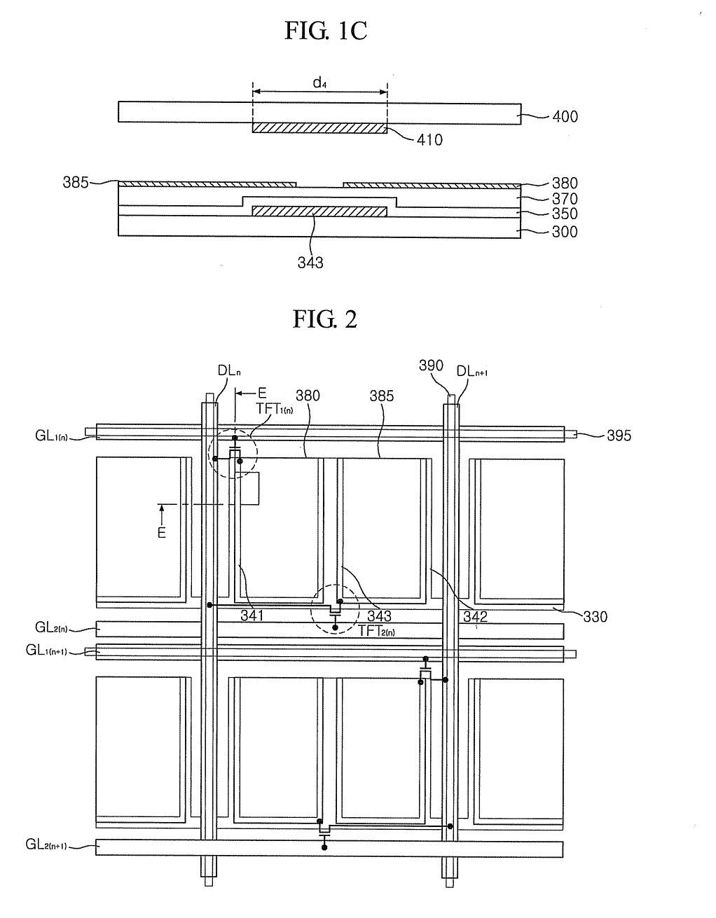

FIG. 2 is a schematic plan view of another exemplary embodiment of an LCD according to the present invention.

The exemplary embodiment of the LCD according to the present invention shown in FIG. 2 is different from that shown in FIG. 1 in that a plurality of shielding lines are formed on first gate lines as well as on the data lines. Since the other components are substantially the same, only different configurations will be described below.

The thin film transistor substrate includes a plurality of gate lines that are formed on a transparent insulative substrate 300 to transmit gate signals and are composed of a plurality of first gate lines GL₁₍ₙ₎ and GL₁₍ₙ₊₁₎ laterally formed on the substrate and a plurality of second gate lines GL₂₍ₙ₎ and GL₂₍ₙ₊₁₎ formed while being spaced apart by a predetermined distance from the first gate lines GL₁₍ₙ₎ and GL₁₍ₙ₊₁₎; storage capacitor electrode lines 330 that are formed in parallel with the plurality of gate lines and have storage capacitor electrodes; a plurality of data lines DLₙ and DLₙ₊₁ that are formed to intersect the plurality gate lines while being insulated therefrom; a plurality of unit pixels that are composed of a plurality of first unit pixels and a plurality of second unit pixels and formed in regions where the plurality of gate lines and the plurality of data lines intersect each other; and a plurality of shielding lines 390 and 395 which are formed on the data lines and the first gate lines, respectively, and to which a predetermined voltage is applied.

The plurality of shielding lines 390 are formed on the data lines to be parallel therewith, and the width of each of the plurality of shielding lines 390 is formed to be smaller than that of the data line. Preferably, the width of the data line is set to 5.5 μm, and the width of the shielding line 390 is set to 5 μm. Further, the plurality of shielding lines 395 are formed on the first gate lines to be parallel therewith, and the width of each of the plurality of shielding lines 395 is formed to be smaller than that of the first gate line. Meanwhile, although this embodiment has been described in connection with an example in which the plurality of shielding lines 395 are formed on the first gate lines, it is not limited thereto, but the plurality of shielding lines 395 may be formed on the second gate lines or on the first and second gate lines. If the plurality of shielding lines 395 are also formed on the gate lines as described above, problems of the occurrence of a short circuit in the plurality of shielding lines 390 formed on the data lines, and the like can be solved.

The plurality of shielding lines 390 and 395 are made of the same material as the pixel electrodes 380 and 385. The pixel electrodes 380 and 385 are generally made of a transparent conductive material such as indium tin oxide (ITO) or indium zinc oxide (IZO). Further, to minimize coupling capacitance between the data line and the pixel electrode due to a pixel signal applied to the data line, a voltage with the same amplitude as that of a voltage applied to the storage capacitor electrode is applied to the plurality of shielding lines 390 and 395 via the storage capacitor electrode line 330. That is, a voltage with the same amplitude as that of the common voltage applied to the color filter substrate is applied to the plurality of shielding lines 390 and 395.

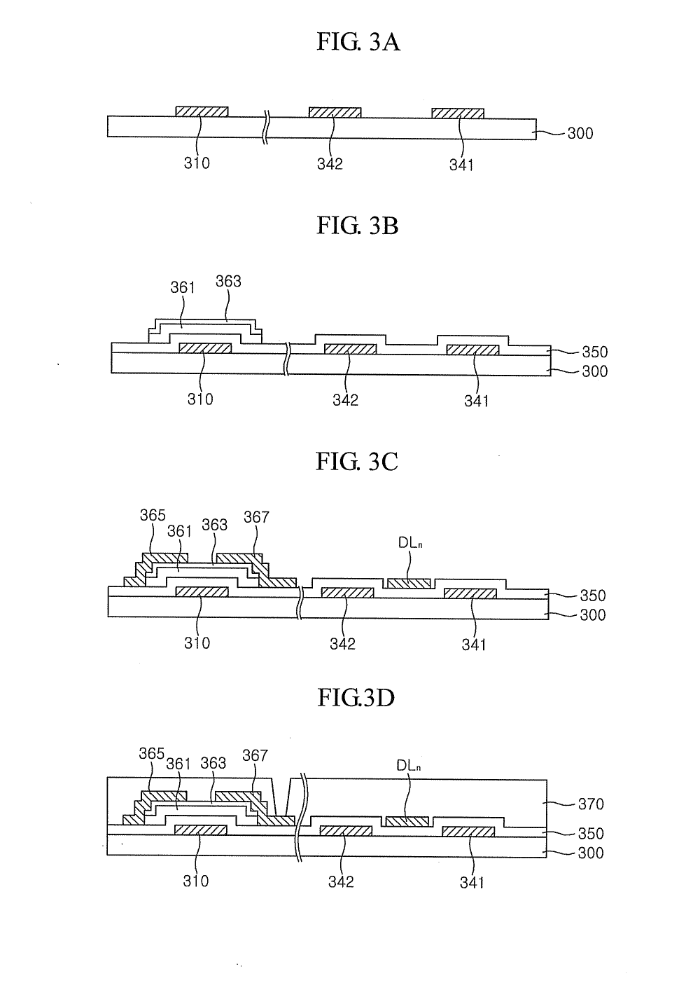

FIGS. 3A to 3E are cross-sectional views illustrating a process of fabricating a thin film transistor substrate of the LCD shown in FIG. 2. The cross-sectional views of the thin film transistor substrate shown in FIGS. 3A to 3E are schematic cross-sectional views taken along line E-E in FIG. 2. The thin film transistor substrate includes a first thin film transistor TFT₁₍ₙ₎, first and second pixel electrodes 380 and 385, first and second storage capacitor electrodes 341 and 342, and a shielding line 390.

First, referring to FIG. 3A, a first conductive film is formed on a transparent insulative substrate 300, and a gate electrode 310 and first and second storage capacitor electrodes 341 and 342, which have predetermined line widths, are then formed on the transparent insulative substrate 300 by means of an etching process using a first photosensitive film-mask pattern (not shown).

The first conductive film is first formed on the transparent insulative substrate 300 by means of a vapor deposition method using chemical vapor deposition (“CVD ”), physical vapor deposition (“PVD ”), sputtering or the like. Preferably, at least any one of Cr, MoW, Cr/Al, Cu, Al(Nd), Mo/Al, Mo/Al(Nd) and Cr/Al(Nd) is used for the first conductive film, and the first conductive film may be formed as a multi-layered film. Thereafter, a photosensitive film is applied, and a photolithography process using a first mask is then performed to form the first photosensitive film-mask pattern. An etching process is performed using the first photosensitive film-mask pattern as an etching mask to form the gate electrode 310 and the first and second storage capacitor electrodes 341 and 342 as shown in FIG. 3A. Thereafter, a predetermined stripping process is performed to remove the first photosensitive film-mask pattern.

Referring to FIG. 3B, a gate insulation film 350, an active layer 361 and an ohmic contact layer 363 are sequentially formed on the entire surface of the substrate 300 shown in FIG. 3A, and an etching process using a second photosensitive film-mask pattern (not shown) is then performed to form an active region of the thin film transistor.

The gate insulation film 350 is formed on the substrate by means of a vapor deposition method using plasma enhanced chemical vapor deposition (“PECVD ”), sputtering or the like. At this time, it is preferred that an inorganic insulating material including a silicone oxide or silicone nitride be used for the gate insulation film 350. The active layer 361 and the ohmic contact layer 363 are sequentially formed on the gate insulation film 350 by means of the aforementioned vapor deposition method. An amorphous silicone layer is used as the active layer 361, and a silicide layer or an amorphous silicone layer doped with highly concentrated N-type impurities is used as the ohmic contact layer 363. Thereafter, a photosensitive film is applied to the ohmic contact layer 363, and the second photosensitive film-mask pattern is then formed by means of a photolithography process using a second mask. An etching process, in which the second photosensitive film-mask pattern is used as an etching mask and the gate insulation film 350 is used as an etching stop film, is performed to remove the ohmic contact layer 363 and the active layer 361 so that an active region is formed on the gate electrode 310. Thereafter, a predetermined stripping process is performed to remove the second photosensitive film-mask pattern.

Referring to FIG. 3C, a second conductive film is formed on the entire surface of the substrate 300 having the active region of the thin film transistor formed thereon, and an etching process is performed using a third photosensitive film-mask pattern (not shown) so that a data line DLₙ, a source electrode 365 and a drain electrode 367 can be formed on the substrate 300.

The second conductive film is formed on the entire surface of the substrate 300 by means of a vapor deposition method using CVD, PVD, sputtering or the like. At this time, it is preferred that a single metallic layer made of at least one of Mo, Al, Cr and Ti, or multiple layers thereof be used as the second conductive film. It will be apparent that the second conductive film is made of the same material as the first conductive film. A photosensitive film is applied to the second conductive film, and a lithography process is then performed using a mask to form the third photosensitive film-mask pattern. An etching process is performed using the third photosensitive film-mask pattern as an etching mask to etch a second conductive film, and the third photosensitive film-mask pattern is then removed. Thereafter, an etching process using the etched second conductive film as an etching mask is performed to remove the ohmic contact layer 363 in a region exposed between the second conductive films so that a channel defined by the active layer 361 can be formed between the source and drain electrodes 365 and 367.

Referring to FIG. 3D, an organic film 370 is formed on the entire surface of the substrate 300 having the thin film transistor and the data line formed thereon, and a portion of the organic film 370 is removed by means of an etching process using a fourth photosensitive film-mask pattern (not shown) to form a contact hole. At this time, it is preferred that the organic film 370 be formed to have a thickness of 4 μm to 6 μm.

Referring to FIG. 3E, a third conductive film is formed on the organic film 370, and the third conductive film is then patterned using a fifth photosensitive film-mask pattern (not shown) so that the pixel electrodes 380 and 385 and a shielding line 390 can be formed. At this time, it is preferred that the third conductive film be made of a transparent conductive film including ITO or IZO.

The third conductive film is formed on the entire surface of the substrate 300 having the organic film 370 formed thereon, a photosensitive film is then applied thereto, and a photolithography process is performed using a mask to form the fifth photosensitive film-mask pattern. Remaining regions except the regions of the pixel electrodes 380 and 385 and the shielding line 390 are opened through the fifth photosensitive film-mask pattern. Next, the opened regions of the third conductive film are removed through an etching process using the fifth photosensitive film-mask pattern as an etching mask, and the fifth photosensitive film-mask pattern is removed through a predetermined stripping process to form the pixel electrodes 380 and 385 and the shielding line 390.

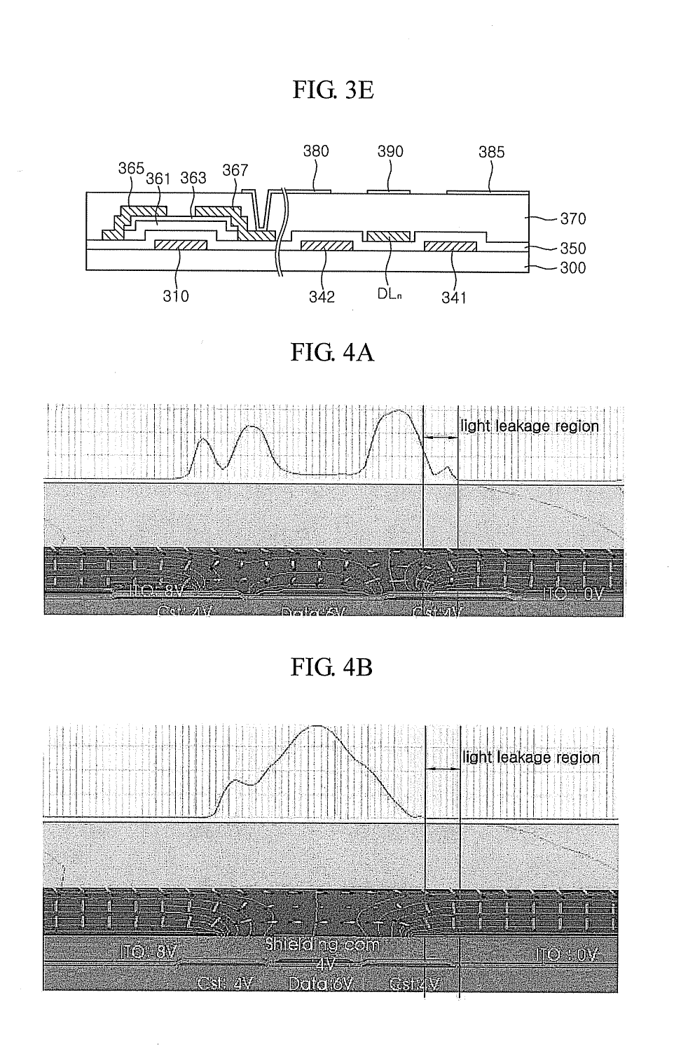

FIGS. 4A and 4B are graphs illustrating results of light leakage simulations of LCDs according to a prior art LCD and an LCD of the present invention, respectively.

FIG. 4A illustrates results of a light leakage simulation of an LCD in which a shielding line is not formed, and FIG. 4B illustrates results of a light leakage simulation of an exemplary embodiment of an LCD in which a shielding line is formed. If a voltage (4V in this exemplary embodiment) with the same amplitude as that of a voltage applied to the storage capacitor electrode is applied to the shielding line, an electric field is changed and the arrangement of liquid crystals is changed. As a result, it can be seen that a light leakage region of the LCD according to the present invention is formed more narrowly than that of the LCD according to the prior art, and the light leakage region is formed to be narrower by at least 3 μm as compared with the prior art. Thus, the width of the black matrix formed on the data line of the color filter substrate can be decreased by at least 3 μm, resulting in improvement of an aperture ratio by about 10% as compared with the prior art. Although only a TN mode has been described in the exemplary embodiment of the present invention, it is not limited thereto, but a VA mode may be included in the scope of the present invention.

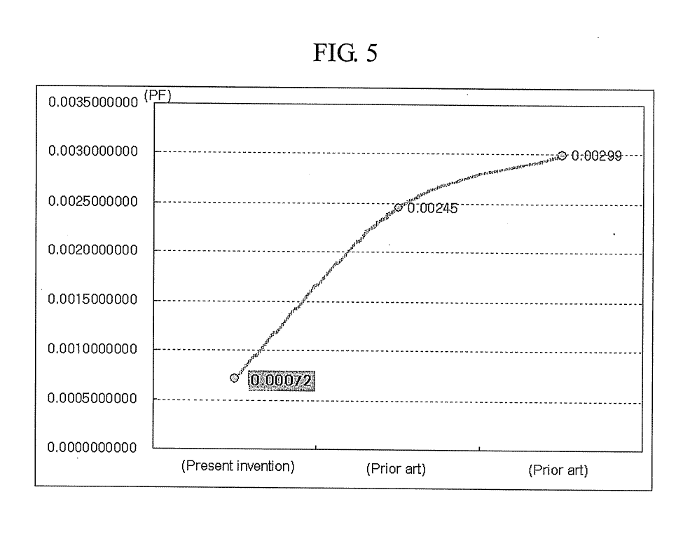

FIG. 5 is a graph illustrating comparison of coupling capacitance values between a data line and a pixel electrode according to the prior art and the present invention, respectively.

Referring to FIG. 5, a coupling capacitance value between the data line and the pixel electrode according to the prior art is about 0.003 pF, whereas a coupling capacitance value between the data line and the pixel electrode according to the present invention is about 0.00072 pF. As a result, the coupling capacitance value is decreased by about 76% in the present invention as compared with the prior art, thereby preventing the occurrence of a phenomenon in which a vertical stripe pattern appears.

As described above, according to the present invention, a plurality of shielding lines to which a predetermined voltage is applied are formed on data lines or both data and gate lines to reduce coupling capacitance between the data line and a pixel electrode of a unit pixel, thereby preventing the occurrence of a phenomenon in which a vertical stripe pattern is shown and thus improving an aperture ratio.

The foregoing are merely exemplary embodiments of a thin film transistor substrate, a method of fabricating the same, and a liquid crystal display having the thin film transistor substrate according to the present invention. The present invention is not limited thereto. It will be readily understood by those skilled in the art that various modifications and changes can be made thereto without departing from the technical spirit and scope of the present invention defined by the appended claims.

What is claimed is:

1. A thin film transistor substrate, comprising:
a plurality of gate lines including a plurality of first gate lines formed in one direction on a substrate and a plurality of second gate lines formed in the same one direction while being spaced apart by a predetermined distance from the first gate lines;
a plurality of data lines formed to intersect the plurality of gate lines while being insulated therefrom;
a plurality of unit pixels including a plurality of first unit pixels and a plurality of second unit pixels, each of the unit pixels are formed at intersection regions of the plurality of gate lines and the plurality of data lines; and
a plurality of shielding lines formed between the unit pixels such that a predetermined voltage is applied to the shielding lines.

2. The thin film transistor substrate as claimed in claim 1, wherein the plurality of shielding lines are formed on the data lines.

3. The thin film transistor substrate as claimed in claim 2, wherein the plurality of shielding lines are formed in parallel with the data lines.

4. The thin film transistor substrate as claimed in claim 2, wherein a width of each of the plurality of shielding lines is formed to be smaller than a width of the respective data line.

5. The thin film transistor substrate as claimed in claim 1, wherein a first thin film transistor of the first unit pixel is connected to the first gate line, and a second thin film transistor of the second unit pixel is connected to the second gate line.

6. The thin film transistor substrate as claimed in claim 2, wherein an organic film is formed between the plurality of shielding lines and the corresponding data lines.

7. The thin film transistor substrate as claimed in claim 2, wherein the plurality of shielding lines are formed on at least one of the plurality of the first gate lines and the plurality of the second gate lines.

8. The thin film transistor substrate as claimed in claim 7, wherein the plurality of shielding lines are formed in parallel with the plurality of gate lines.

9. The thin film transistor substrate as claimed in claim 7, wherein a width of each of the plurality of shielding lines is formed to be smaller a width of the respective gate line.

10. The thin film transistor substrate as claimed in claim 1, wherein the unit pixel further includes a storage capacitor electrode for maintaining a voltage applied to a liquid crystal.

11. The thin film transistor substrate as claimed in claim 10, wherein the amplitude of the predetermined voltage applied to the plurality of shielding lines is the same as a voltage applied to the storage capacitor electrode.

12. A liquid crystal display (LCD), comprising:
a thin film transistor substrate including:
a plurality of gate lines including a plurality of first gate lines formed in one direction on a substrate and a plurality of second gate lines formed in the same one direction while being spaced apart by a predetermined distance from the first gate lines;
a plurality of data lines formed to intersect the plurality of gate lines while being insulated therefrom;
a plurality of unit pixels including a plurality of first unit pixels and a plurality of second unit pixels, each of the unit pixels are formed at intersection regions of the plurality of gate lines and the plurality of data lines; and
a plurality of shielding lines formed between the unit pixels such that a predetermined voltage is applied to the shielding lines.

13. The LCD as claimed in claim 12, wherein the plurality of shielding lines are formed on at least one of the data lines, first gate lines and the second gate lines.

14. The LCD as claimed in claim 13, wherein an organic film is formed between the plurality of shielding lines and the respective at least one of the data lines, first gate lines and the second gate lines.

15. A method of fabricating a thin film transistor substrate, the method comprising:
forming a plurality of gate lines including a plurality of first gate lines formed in one direction on a substrate and a plurality of second gate lines formed in the same one direction while being spaced apart by a predetermined distance from the first gate lines;
forming a plurality of data lines formed to intersect the plurality of gate lines while being insulated therefrom;
forming a plurality of unit pixels including a plurality of first unit pixels and a plurality of second unit pixels, each of the unit pixels are formed at intersection regions of the plurality of gate lines and the plurality of data lines;
forming an organic film on at least one of the plurality of data lines, the plurality of first gate lines and the plurality of second gate lines; and
forming a plurality of shielding lines on the organic film formed between the unit pixels such that a predetermined voltage is applied to the shielding lines.

16. An LCD comprising:
a plurality of pixel rows having a plurality of pixels having switching elements;
a plurality of pairs of first and second gate lines that are separated from each other and connected to the switching elements to transmit a gate-on voltage for turning on the switching elements;
data lines connected to the switching elements to transmit a pixel voltage, each of the data lines being connected to two adjacent pixel columns; an organic film formed on at least one of the data lines, first gate lines and second gate lines; and
shielding lines formed on the organic film.

17. The LCD as claimed in claim 16, wherein each of the pairs of first and second gate lines is positioned between two adjacent pixel rows and connected to one of the two pixel rows.

18. The LCD as claimed in claim 17, wherein the two adjacent pixel columns are positioned at opposite sides with respect to each of the data lines.

19. The LCD as claimed in claim 17, wherein the two adjacent pixel columns are positioned at the same side with respect to each of the data lines.

20. The LCD as claimed in claim 15, wherein the LCD performs a column inversion.
